(19) United States
(12) Patent Application Publication
(10) Pub. No.: US 2016/0147090 A1
(43) Pub. Date: May 26, 2016

(54) LIQUID CRYSTAL LENS UNIT AND 3D DISPLAY DEVICE

(71) Applicant: SAMSUNG DISPLAY CO., LTD., YONGIN-CITY (KR)

(72) Inventors: SEUNG JUN JEONG, HWASEONG-SI (KR); HYUN SEUNG SEO, ANYANG-SI (KR)

(21) Appl. No.: 14/806,006

(22) Filed: Jul. 22, 2015

(30) Foreign Application Priority Data
Nov. 24, 2014 (KR) 10-2014-0164608

(51) Int. Cl. G02F 1/137; G02F 1/1335; H01L 27/32; G02F 1/13363; G02F 1/1343; G02B 27/22; G02F 1/29; G02F 1/1337

(52) U.S. Cl. CPC G02F 1/137; G02F 1/29; G02F 1/133528; G02F 1/1337; G02F 1/13363; G02F 1/134309; G02F 1/13439; G02B 27/2214; H01L 27/3232

(57) ABSTRACT

A liquid crystal lens unit includes: a plurality of first electrodes positioned on a first substrate, each extending in a first direction in which the first electrodes are tilted by θ degrees, and each spaced apart from each other in a second direction substantially perpendicular to the first direction; a second electrode positioned on the plurality of first electrodes that has a plate shape; a second substrate positioned on the second electrode; and a liquid crystal layer positioned between the plurality of first electrodes and the second electrode.

### CROSS-REFERENCE TO RELATED APPLICATION

This application claims priority from Korean Patent Application No. 10-2014-0164608 filed in the Korean Intellectual Property Office on Nov. 24, 2014, and all the benefits accruing therefrom, the contents of which are herein incorporated by reference in their entirety.

### BACKGROUND

(a) Technical Field

Embodiments of the present disclosure are directed to a liquid crystal lens unit and a 3D display device. More particularly, embodiments of the present disclosure are directed to a liquid crystal lens unit capable of implementing a 2D image and a 3D image, and a 3D display device including the same.

(b) Discussion of the Related Art

In general, factors by which persons perceive a three-dimensional (3D) effect include a physiological factor and an experimental factor. In a 3D image display technology, a 3D effect of an object is perceived using binocular parallax, which is the primary factor by which a 3D effect is perceived at a short distance. An example of a binocular parallax scheme as described above includes a stereoscopic scheme in which glasses are worn and an autostereoscopic scheme in which no glasses are worn.

Autostereoscopic schemes include a parallax barrier scheme and a liquid crystal lens scheme. Recently, a liquid crystal lens unit in which a Fresnel lens is formed by a liquid crystal lens and a 3D display device including the same have been developed.

### SUMMARY

Embodiments of the present disclosure can provide a liquid crystal lens unit and a 3D display device having improved light transmittance when implementing a 3D image.

Further, embodiments of the present disclosure can provide a liquid crystal lens unit and a 3D display device that can prevent refracted light from being distorted when implementing a 3D image.

An exemplary embodiment of the present disclosure provides a liquid crystal lens unit that includes: a plurality of first electrodes positioned on a first substrate, each extending in a first direction in which the first electrodes are tilted by θ degrees, and each spaced apart from each other in a second direction substantially perpendicular to the first direction; a second electrode positioned on the plurality of first electrodes that has a plate shape; a second substrate positioned on the second electrode; and a liquid crystal layer positioned between the plurality of first electrodes and the second electrode.

Liquid crystal molecules of the liquid crystal layer may be aligned in a direction of θ+90 degrees.

The liquid crystal lens unit may further include a first alignment layer positioned between the first electrodes and the liquid crystal layer that has a first alignment direction of θ+90 degrees.

The liquid crystal lens unit may further include a second alignment layer positioned between the second electrode and the liquid crystal layer that has the first alignment direction.

After a same common voltage is applied to each of the plurality of first electrodes, different voltages may be applied to each of the first electrodes that neighbor each other.

The common voltage may be equal to or larger than a minimum voltage value for driving liquid crystal molecules of the liquid crystal layer.

The liquid crystal layer forms a Fresnel lens when different voltages are respectively applied to the plurality of first electrodes.

Another exemplary embodiment of the present disclosure provides a 3D display device that includes: a display panel for displaying an image; and a liquid crystal lens unit positioned on the display panel that includes a plurality of first electrodes positioned on a first substrate, each extending in a direction in which the first electrodes are tilted by θ degrees, and each spaced apart from each other in a second direction substantially perpendicular to the first direction, a second electrode positioned on the plurality of first electrodes that has a plate shape, a second substrate positioned on the second electrode, and a liquid crystal layer positioned between the plurality of first electrodes and the second electrode.

The 3D display device may further include a polarizer positioned between the display panel and the liquid crystal lens unit; and a phase retardation plate positioned between the polarizer and the liquid crystal lens unit.

The polarizer may have a linear polarization axis of 0 degrees.

The phase retardation plate may have a λ/2 phase retardation axis of θ/2 degrees.

Liquid crystal molecules of the liquid crystal layer may be aligned in a direction of θ+90 degrees.

The liquid crystal lens unit may further include a first alignment layer positioned between the first electrodes and the liquid crystal layer that has a first alignment direction of θ+90 degrees.

The liquid crystal lens unit may further include a second alignment layer positioned between the second electrode and the liquid crystal layer that has the first alignment direction.

After a same common voltage is applied to each of the plurality of first electrodes, different voltages may be applied to each of the first electrodes that neighbor to each other.

The common voltage may be equal to or greater than a minimum voltage value for driving the liquid crystal molecules of the liquid crystal layer.

The liquid crystal layer may form a Fresnel lens when different voltages are respectively applied to the plurality of first electrodes, respectively.

The display panel may include a liquid crystal.

The display panel may include an organic light emitting diode.

Another exemplary embodiment of the present disclosure provides a liquid crystal lens unit that includes a plurality of first electrodes positioned on a first substrate, each extending in a first direction in which the first electrodes are tilted by θ degrees, and each spaced apart from each other in a second direction substantially perpendicular to the first direction; a second electrode positioned on the plurality of first electrodes that has a plate shape; and a liquid crystal layer positioned between the plurality of first electrodes and the second electrode. After a same common voltage is applied to each of the plurality of first electrodes, different voltages are applied to neighboring first electrodes wherein the liquid crystal layer forms a Fresnel lens.

As set forth above, according to an exemplary embodiment of the present disclosure, a liquid crystal lens unit and a 3D display device has improved light transmittance when displaying a 3D image.

Further, a liquid crystal lens unit and a 3D display device according to an exemplary embodiment of the present disclosure can prevent refracted light from being distorted when displaying a 3D image.

### BRIEF DESCRIPTION OF THE DRAWINGS

FIG. 1 is a cross-sectional view of a 3D display device according to an exemplary embodiment of the present disclosure.

FIG. 2 illustrates an optical axis of an image displayed from the 3D display device shown in FIG. 1.

FIGS. 3(A) to (C) a show a liquid crystal and electrodes of a liquid crystal lens unit shown in FIG. 1.

FIG. 4 illustrates a liquid crystal lens unit according to Comparative Example 1.

FIG. 5 shows graphs of a phase distribution and transmittance distribution of a liquid crystal lens unit according to Comparative Example 1.

FIG. 6 illustrates a liquid crystal lens unit according to Comparative Example 2.

FIG. 7 shows graphs of a phase distribution and transmittance distribution of the liquid crystal lens unit according to Comparative Example 2.

FIG. 8 illustrates a liquid crystal lens unit according to an Experimental Example.

FIG. 9 shows graphs of a phase distribution and transmittance distribution of the liquid crystal lens unit according to an Experimental Example.

FIGS. 10(A) to (C) show movement of a liquid crystal of a liquid crystal lens unit according to an Experimental Example.

### DETAILED DESCRIPTION OF EXEMPLARY EMBODIMENTS

Hereinafter, several exemplary embodiments of the present disclosure will be described in detail with reference to the accompanying drawings so that those skilled in the art to which the present disclosure pertains may easily practice the present disclosure. However, the present disclosure may be implemented in various different forms and is not limited to exemplary embodiments provided herein.

Components having the same configuration may be described using the same reference numerals, and only components different from those of an exemplary embodiment will be described in the other exemplary embodiments.

In the drawings, the thickness of layers, films, panels, regions, etc., may be exaggerated for clarity. It will be understood that when an element such as a layer, a film, a region, or a substrate is referred to as being “on” another element, it may be directly on another element or may have an intervening element present therebetween.

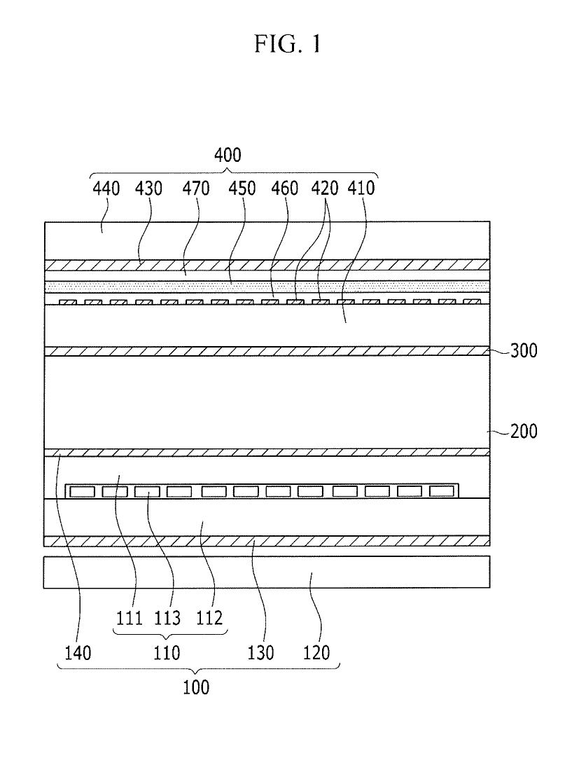

Hereinafter, a 3D display device according to an exemplary embodiment of the present disclosure will be described with reference to FIGS. 1 to 3C.

FIG. 1 is a cross-sectional view of a 3D display device according to an exemplary embodiment of the present disclosure.

As shown in FIG. 1, a 3D display device according to an exemplary embodiment of the present disclosure includes a display panel 100, an interval unit 200, a phase retardation plate 300, and a liquid crystal lens unit 400.

The display panel 100 may display a 2D image, which is a planar image, and may be an organic light emitting diode display (OLED) that includes an organic light emitting diode, a liquid crystal display device (LCD) that includes liquid crystals, etc. A liquid crystal display device will be described as an example of the display panel 100 in an exemplary embodiment of the present disclosure, however, embodiments of the disclosure are not limited thereto.

The display panel 100 includes a display unit 110 that includes two substrates 111 and 112 and a liquid crystal unit 113 positioned between the two substrates 111 and 112 and a backlight unit 120 that irradiates light to the display unit 110. The two substrates 111 and 112 may include a substrate main body made of glass, plastic, metal, etc., and metal patterns formed on the substrate main body that are used as electrodes An electric field may be formed in a longitudinal direction or a transverse direction in a space between the two substrates and liquid crystals of the liquid crystal unit serve as a shutter depending on the electric field in the space, such that the display panel 100 displays a 2D image.

The display panel 100 may display a 2D image for a left eye and another 2D image for a right eye so that a user may perceive a 3D image.

The display panel 100 includes a first polarizer 130 positioned between the display unit 110 and the backlight unit 120 and a second polarizer 140 positioned between the display unit 110 and the liquid crystal lens unit 400. However, although the second polarizer 140 is included in the display panel 100 in an exemplary embodiment of the present disclosure, the present disclosure is not limited thereto. That is, the second polarizer may be excluded from a display panel in another exemplary embodiment of the present disclosure.

Each of the first polarizer 130 and the second polarizer 140 may a linear polarizer having a linear polarization axis. The first polarizer 130 and the second polarizer 140 may have linear polarization axes in the same direction or have linear polarization axes in directions that intersect each other. In an exemplary embodiment, the second polarizer 140 may have a linear polarization axis of 0 degrees.

The interval unit 200 is positioned between the display panel 100 and the liquid crystal lens unit 400 and sets an interval between the display panel 100 and the liquid crystal lens unit 400 so that a 2D image displayed from the display panel 100 through the liquid crystal lens unit 400 may be perceived as a 3D image.

Alternatively, in another exemplary embodiment of the present disclosure, the interval unit 200 may be omitted.

The phase retardation plate 300, which may be a λ/2 phase retardation plate, is positioned between the display panel 100 and the liquid crystal lens unit 400. The phase retardation plate 300 retards an optical axis of light that forms the image displayed from the display panel 100. For example, a λ/2 phase retardation plate 300 may have a phase retardation axis of θ/2 degrees, so that light passing from the display unit 110 through the second polarizer 140, which has an optical axis of 0 degree, may have an optical axis of θ degrees.

The liquid crystal lens unit 400 is positioned above the display panel 100 with the phase retardation plate 300 interposed therebetween. The liquid crystal lens unit 400 includes a first substrate 410, first electrodes 420, a second electrode 430, a second substrate 440, a liquid crystal layer 450, a first alignment layer 460, and a second alignment layer 470.

The first substrate 410, the first electrodes 420, the first alignment layer 460, the second alignment layer 470, the second electrode 430, and the second substrate 440 are sequentially stacked.

The first electrodes 420 and the first alignment layer 460 may be disposed on the first substrate 410, and the second electrode 430 and the second alignment layer 470 may be disposed on the second substrate 440.

The first substrate 410 and the second substrate 440 may be made of transparent glass, plastic, etc.

The first electrodes 420 may extend in a first direction tilted by θ degrees, the linear polarization axis of the second polarizer 140, on a plane. There may be a plurality of first electrodes 420, and the plurality of first electrodes 420 may be spaced apart from each other in a second direction. Here, the second direction may be substantially perpendicular to the first direction. However, the second direction is not limited thereto, but may form various other angles with respect to the first direction.

The plurality of first electrodes 420 may be formed on the same layer in an exemplary embodiment of the present disclosure. However, embodiments of the present disclosure are not limited thereto. That is, the plurality of first electrodes 420 may be formed on different layers in other exemplary embodiments of the present disclosure.

The second electrode 430 has a plate shape and overlaps the plurality of first electrodes 420.

The liquid crystal layer 450 is positioned between the first electrodes 420 and the second electrode 430, and liquid crystals positioned in the liquid crystal layer 450 are tilted by an electric field that forms based on voltages applied to each of the first electrodes 420 and the second electrode 430. The liquid crystals of the liquid crystal layer 450 align in a direction of θ+90 degrees. In detail, the liquid crystals of the liquid crystal layer 450 have an aspect ratio in which a long side of the liquid crystal extends in a direction of θ+90 degrees with respect to the first direction in which the first electrodes 420 extend.

The first alignment layer 460 is positioned between the first electrodes 420 and the liquid crystal layer 450, and the second alignment layer 470 is positioned between the second electrode 430 and the liquid crystal layer 450. Each of the first alignment layer 460 and the second alignment layer 470 has an alignment direction of θ+90 degrees so that the liquid crystals of the liquid crystal layer 450 are aligned in the direction of θ+90 degrees. That is, the first alignment layer 460 has a first alignment direction of θ+90 degrees, and the second alignment layer 470 has a second alignment direction of θ+90 degrees.

The voltages are applied to the plurality of first electrodes 420 and the second electrode 430 so that an generated by the liquid crystal lens unit 400 may be perceived as a 3D image. The liquid crystal layer 450 may be a Fresnel lens.

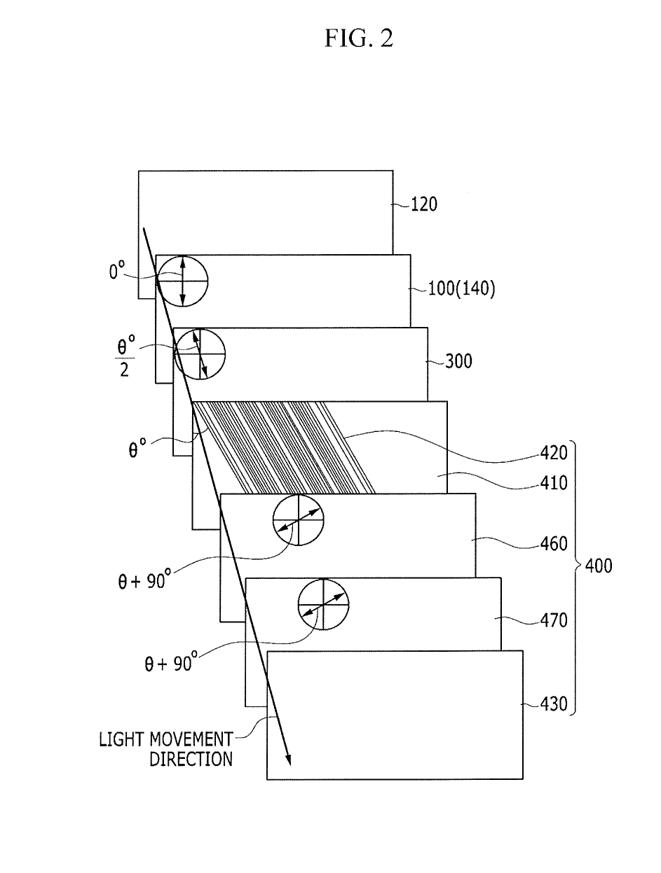

FIG. 2 illustrates an optical axis of an image displayed from the 3D display device shown in FIG. 1.

As shown in FIG. 2, light emitted from the backlight unit 120 of the display panel 100 and incident to the liquid crystal lens unit 400 has an optical axis of 0 degree, while passing through the second polarizer 140 of the display panel 100, and an optical axis of θ degrees while passing through the phase retardation plate 300, which is two times larger than the θ/2 degrees of the phase retardation axis. The light received from the display panel 100 and incident to the liquid crystal lens unit 400 through the phase retardation plate 300 has an optical axis of θ degrees, and each of the plurality of first electrodes 420 is tilted at an angle of θ degrees, which is the same as the optical axis of the incident light, which prevents the optical axis of the light incident from the display panel 100 to the liquid crystal lens unit 400 from being deformed.

The liquid crystal layer 450 is a Fresnel lens formed by the electric field formed by different voltages applied to each of the plurality of first electrodes 420 and the second electrode 430, such that the light incident from the display panel 100 to the liquid crystal lens unit 400 may be perceived as forming a 3D image.

For example, when the liquid crystal layer 450 is a Fresnel lens, the display panel 100 displays n viewpoint images, where n is a natural number, in n continuous pixels. Light for each of the n viewpoint images passes through the second polarizer 140, passes through the phase retardation plate 300, and is then incident to the liquid crystal lens unit 400 with an optical axis of θ degrees. The n viewpoint images are refracted as n viewpoint regions by the Fresnel lens of the liquid crystal layer 450 of the liquid crystal lens unit 400 to be perceived as a 3D image.

According to embodiments, the liquid crystal lens unit 400 of a 3D display device according to an exemplary embodiment of the present disclosure forms a Fresnel lens. However, embodiments of the present disclosure are not limited thereto. That is, a liquid crystal lens unit 400 of a 3D display device according to an exemplary embodiment of the present disclosure may be a lenticular lens.

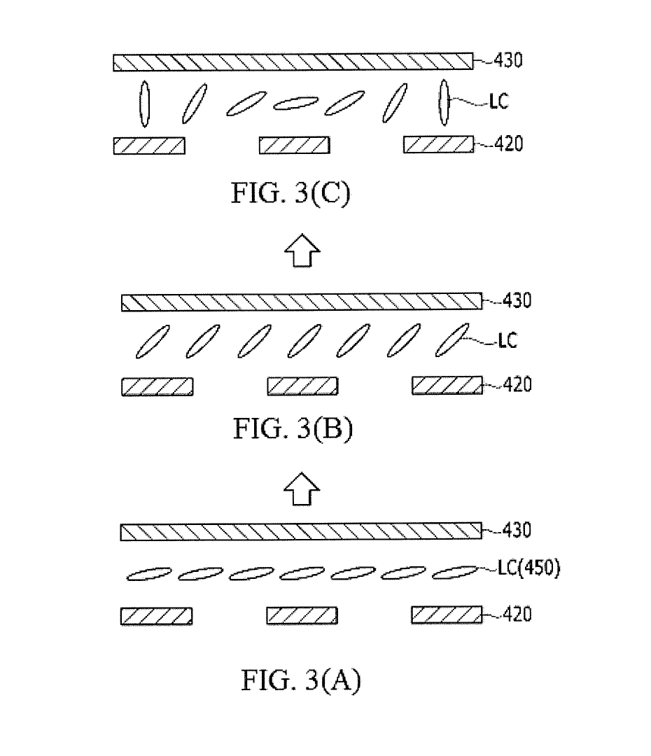

FIGS. 3A to 3C show a liquid crystal and electrodes of a liquid crystal lens unit shown in FIG. 1.

As shown in FIGS. 3A to 3C, for the liquid crystals LC of the liquid crystal layer 450 to form a Fresnel lens, voltages are applied to the plurality of first electrodes 420 and the second electrode 430.

First, as shown in FIG. 3(A), when no voltages are applied to the plurality of first electrodes 420 and the second electrode 430, long sides of the liquid crystals LC are aligned in a direction of θ+90 degrees.

Next, as shown in FIG. 3(B), a voltage is applied to the second electrode 430 and a common voltage is applied to all of the plurality of first electrodes 420. Here, the common voltage may be equal to or greater than a minimum voltage value (Vth) used to drive the liquid crystals LC of the liquid crystal layer 450. Since the same common voltage is applied to all of the plurality of first electrodes 420, each of the liquid crystals LC of the liquid crystal layer 450 is tilted in the same direction by the same electric field formed between the second electrode 430 and each of the plurality of the first electrodes 420, such that the long sides of all the liquid crystals LC are aligned in the same direction.

Next, as shown in FIG. 3(C), different voltages are applied to each of first electrodes 420, and the liquid crystals LC of the liquid crystal layer 450 are tilted in different directions by different electric fields formed between the second electrode 430 and each of the plurality of first electrodes, such that the liquid crystal layer 450 form a Fresnel lens.

As described above, to generate a 3D image is, the liquid crystals LC of the liquid crystal layer 450 of the liquid crystal lens unit 400 are driven, thereby improving light transmittance of the liquid crystal lens unit 400 and preventing refraction of the light. Therefore, a liquid crystal lens unit 400 and a 3D display device having an improved 3D image display quality are provided.

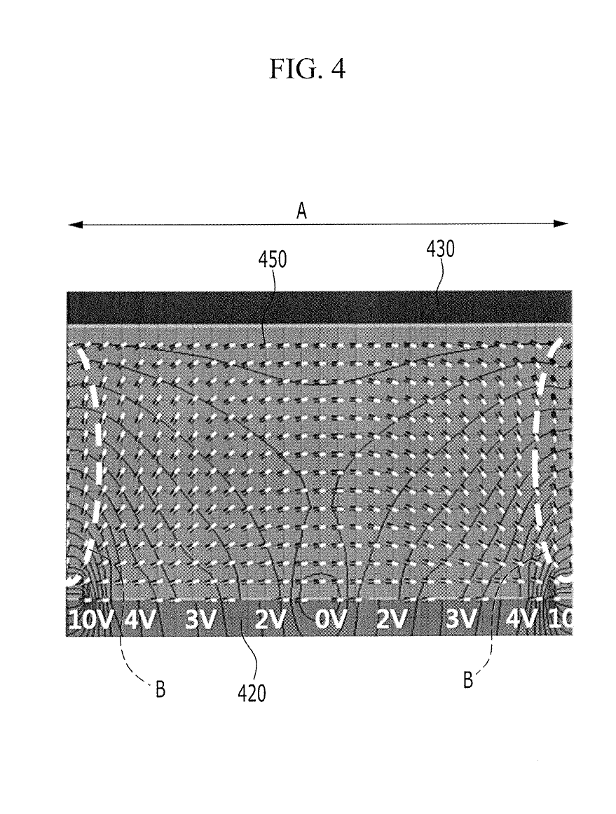

Next, experiments that confirm the above-mentioned effect will be described with reference to FIGS. 4 to 10(C).

FIG. 4 illustrates a liquid crystal lens unit according to Comparative Example 1.

As shown in FIG. 4, Comparative Example 1 is a liquid crystal lens unit in which first electrodes extend in a direction parallel to a direction in which a liquid crystal layer is aligned, and different voltages are respectively applied to a plurality of first electrodes. To form the liquid crystal layer 450 of the liquid crystal lens unit of Comparative Example 1 into a lens, different voltages were respectively applied to the plurality of first electrodes 420.

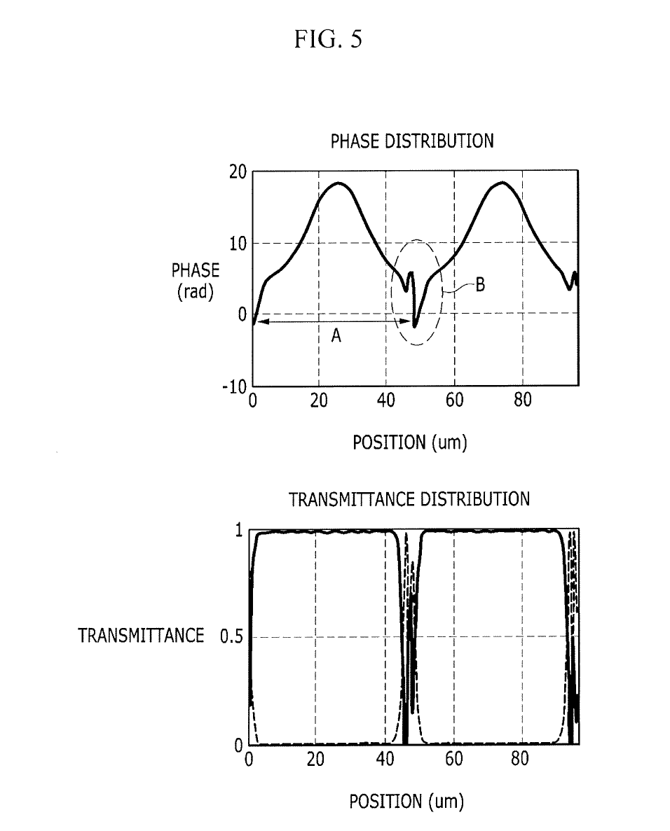

FIG. 5 shows graphs of a phase distribution and a transmittance distribution of the liquid crystal lens unit according to Comparative Example 1.

The phase distribution of light passing through the liquid crystal lens unit of Comparative Example 1 shown in FIG. 5 confirms that refracted light is slightly distorted at a boundary B at an end portion of a lens of a predetermined length A.

In addition, the transmittance distribution of the light passing through the liquid crystal lens unit of Comparative Example 1 confirms that the liquid crystals rotate in a horizontal direction to deform polarization, which deteriorates transmittance. That is, it was confirmed that in a liquid crystal lens unit according to Comparative Example 1, light having a deformed polarization needs to be blocked by an additional polarizer.

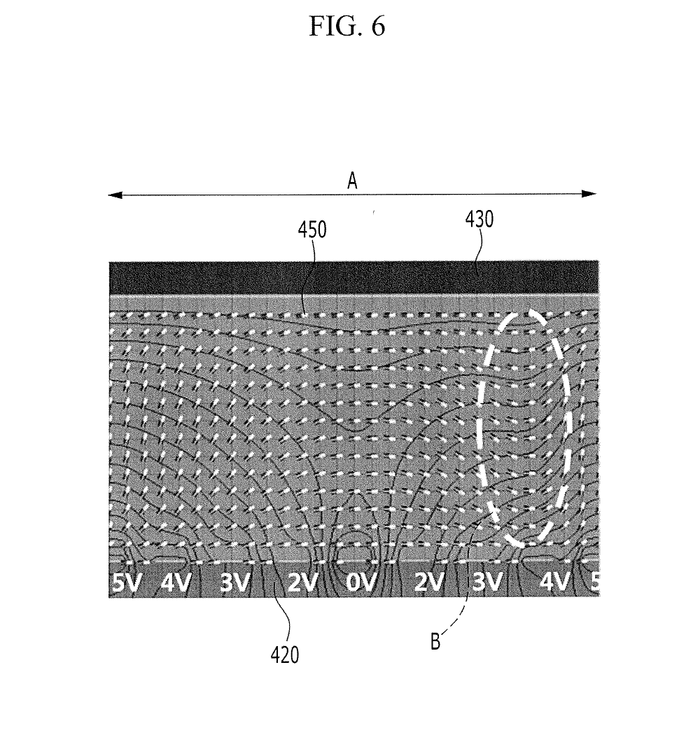

FIG. 6 illustrates a liquid crystal lens unit according to Comparative Example 2.

As shown in FIG. 6, Comparative Example 2 is a liquid crystal lens unit in which first electrodes extend in a direction perpendicular to a direction in which a liquid crystal layer is aligned, and different voltages are respectively applied to a plurality of first electrodes. To form the liquid crystal layer 450 of the liquid crystal lens unit of Comparative Example 2 into a lens, different voltages were respectively applied to the plurality of first electrodes 420.

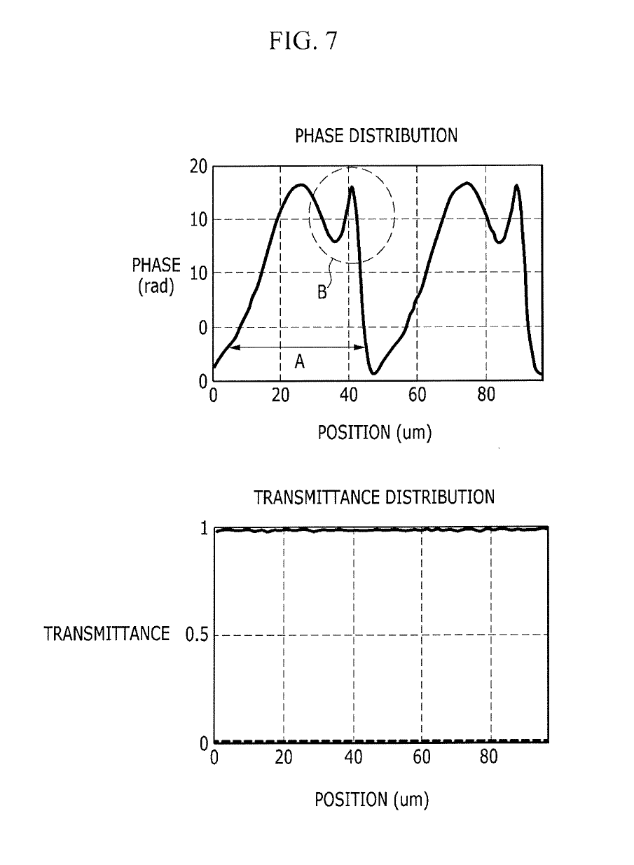

FIG. 7 shows graphs of a phase distribution and transmittance distribution of the liquid crystal lens unit according to Comparative Example 2.

The phase distribution of light passing through the liquid crystal lens unit of Comparative Example 2 shown in FIG. 7 confirm that a refractive index is distorted over a wide interval at a boundary B at an end portion of a lens of a predetermined length A. This means that disclination of the liquid crystals is generated due to interference between neighboring liquid crystals at the boundary B of the lens. That is, it was confirmed that in the liquid crystal lens unit of Comparative Example 2, lens performance itself deteriorated.

In addition, the transmittance distribution of the light passing through the liquid crystal lens unit of Comparative Example 2confirms that there is no change in transmittance.

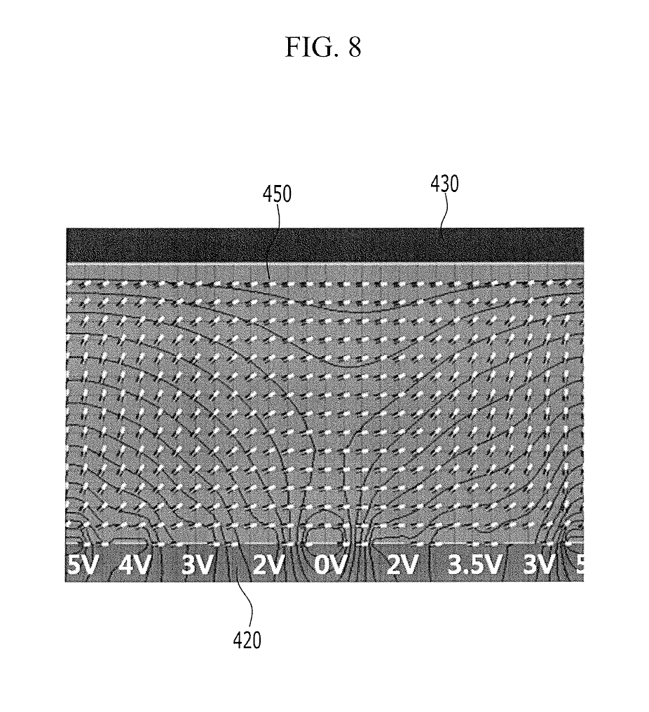

FIG. 8 illustrates a liquid crystal lens unit according to an Experimental Example.

As shown in FIG. 8, an experiment Example is the liquid crystal lens unit according to an exemplary embodiment of the present disclosure described above. An experimental Example is a liquid crystal lens unit in which first electrodes extend in a direction perpendicular to a direction in which a liquid crystal layer is aligned, the same common voltage is applied to all of the plurality of first electrodes within a lens, and different voltages are applied to first electrodes neighboring to each other near a lens boundary. To form the liquid crystal layer 450 of the liquid crystal lens unit of Experimental Example into a lens, different voltages were respectively applied to the plurality of first electrodes 420.

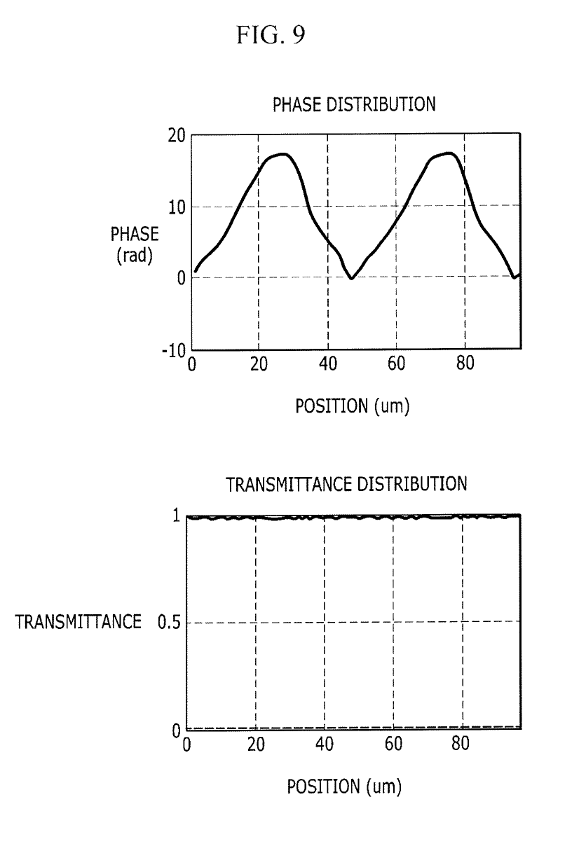

FIG. 9 shows graphs of a phase distribution and transmittance distribution of light of the liquid crystal lens unit according to the Experimental Example.

The phase distribution of light passing through the liquid crystal lens unit of the Experimental Example shown in FIG. 9, confirms that a refractive index is not distorted at a boundary of the lens.

In addition, the transmittance distribution of the light passing through the liquid crystal lens unit of the Experimental Example confirms that there is no change in transmittance.

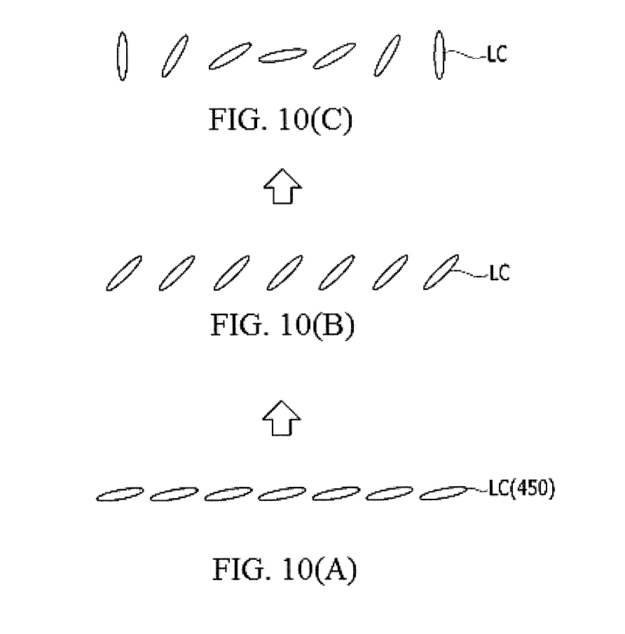

FIGS. 10(A) to (C) show movement of a liquid crystal of the liquid crystal lens unit according to an Experimental Example.

In a liquid crystal lens unit according to an Experimental Example, when no voltages are applied to the plurality of first electrodes, long sides of the liquid crystals LC are aligned in an alignment direction, as shown in FIG. 10(A), and when the same common voltage is applied to all of the plurality of first electrodes, each of the liquid crystals LC is tilted in the same direction, such that the long sides of all the liquid crystals LC are aligned in the same direction, as shown in FIG. 10(B). Then, when different voltages are applied to the plurality of first electrodes, respectively, the liquid crystals LC are tilted in different directions, respectively, such that the liquid crystals form a lens, as shown in FIG. 10(C).

That is, in a liquid crystal lens unit according to an Experimental Example of the present disclosure as compared with the above-mentioned Comparative Example 2, even though the alignment direction of the liquid crystals is perpendicular to the extension direction of the first electrodes, after the common voltage is applied to the plurality of first electrodes to align the long sides of a plurality of liquid crystals, different voltages are applied to the plurality of first electrodes, respectively, to align the long sides of the plurality of liquid crystals in different directions, respectively, which can prevent the disclination of the liquid crystals due to interference between neighboring liquid crystals, and the distortion of refracted light passing through the liquid crystal lens unit.

In addition, in a liquid crystal lens unit according to an Experimental Example of the present disclosure as compared with the above-mentioned Comparative Example 1, since the alignment direction of the liquid crystals is not parallel to the extension direction of the first electrodes, but is perpendicular to the extension direction of the first electrodes, polarization deformation due to liquid crystal rotation in the horizontal direction is prevented, no additional polarizer is used, which can prevent deterioration of transmittance of the light passing through the liquid crystal lens unit.

Through an Experimental Example as descried above, in the 3D display device that includes the liquid crystal lens unit 400 according to an exemplary embodiment of the present disclosure, the transmittance of the light passing through the liquid crystal lens unit 400 is improved and the distortion of refracted light is prevented, when a 3D image is generated. Therefore, the liquid crystal lens unit 400 and a 3D display device having the same may have improved 3D image display quality.

While this disclosure has been described in connection with what is presently considered to be practical exemplary embodiments, it is to be understood that the disclosure is not limited to the disclosed embodiments, but, on the contrary, is intended to cover various modifications and equivalent arrangements included within the spirit and scope of the appended claims.

What is claimed is:

1. A liquid crystal lens unit comprising:
a plurality of first electrodes positioned on a first substrate, each extending in a first direction in which the first electrodes are tilted by θ degrees, and each spaced apart from each other in a second direction substantially perpendicular to the first direction;
a second electrode positioned on the plurality of first electrodes that has a plate shape;
a second substrate positioned on the second electrode; and
a liquid crystal layer positioned between the plurality of first electrodes and the second electrode.

2. The liquid crystal lens unit of claim 1, wherein:
liquid crystal molecules of the liquid crystal layer are aligned in a direction of θ+90 degrees.

3. The liquid crystal lens unit of claim 2, further comprising:
a first alignment layer positioned between the first electrodes and the liquid crystal layer that has a first alignment direction of θ+90 degrees.

4. The liquid crystal lens unit of claim 3, further comprising:
a second alignment layer positioned between the second electrode and the liquid crystal layer that has the first alignment direction.

5. The liquid crystal lens unit of claim 1, wherein:
after a same common voltage is applied to each of the plurality of first electrodes, different voltages are applied to each of the first electrodes that neighbor each other.

6. The liquid crystal lens unit of claim 5, wherein:
the common voltage is equal to or greater than a minimum voltage value for driving liquid crystal molecules of the liquid crystal layer.

7. The liquid crystal lens unit of claim 5, wherein:
the liquid crystal layer forms a Fresnel lens when different voltages are respectively applied to the plurality of first electrodes.

8. A three-dimensional (3D) display device comprising:
a display panel configured to display an image; and
a liquid crystal lens unit positioned on the display panel that includes a plurality of first electrodes positioned on a first substrate, each extending in a first direction in which the first electrodes are tilted by θ degrees, and each spaced apart from each other in a second direction substantially perpendicular to the first direction, a second electrode positioned on the plurality of first electrodes that has a plate shape, a second substrate positioned on the second electrode, and a liquid crystal layer positioned between the plurality of first electrodes and the second electrode.

9. The 3D display device of claim 8, further comprising:
a polarizer positioned between the display panel and the liquid crystal lens unit; and
a phase retardation plate positioned between the polarizer and the liquid crystal lens unit.

10. The 3D display device of claim 9, wherein:
the polarizer has a linear polarization axis of 0 degrees.

11. The 3D display device of claim 9, wherein:
the phase retardation plate has a λ/2 phase retardation axis of θ/2 degrees.

12. The 3D display device of claim 8, wherein:
liquid crystal molecules of the liquid crystal layer are aligned in a direction of θ+90 degrees.

13. The 3D display device of claim 12, wherein:
the liquid crystal lens unit further includes a first alignment layer positioned between the first electrodes and the liquid crystal layer that has a first alignment direction of θ+90 degrees.

14. The 3D display device of claim 13, wherein:
the liquid crystal lens unit further includes a second alignment layer positioned between the second electrode and the liquid crystal layer that has the first alignment direction.

15. The 3D display device of claim 8, wherein:
after a same common voltage is applied to each of the plurality of first electrodes, different voltages are applied to each of the first electrodes that neighbor each other.

16. The 3D display device of claim 15, wherein:
the common voltage is equal to or greater than a minimum voltage value for driving the liquid crystal molecules of the liquid crystal layer.

17. The 3D display device of claim 15, wherein:
the liquid crystal layer forms a Fresnel lens when different voltages are respectively applied to the plurality of first electrodes.

18. The 3D display device of claim 8, wherein:
the display panel includes a liquid crystal.

19. The 3D display device of claim 8, wherein:
the display panel includes an organic light emitting diode.

20. A liquid crystal lens unit comprising:
a plurality of first electrodes positioned on a substrate, each extending in a first direction in which the first electrodes are tilted by θ degrees, and each spaced apart from each other in a second direction substantially perpendicular to the first direction;
a second electrode positioned on the plurality of first electrodes that has a plate shape; and
a liquid crystal layer positioned between the plurality of first electrodes and the second electrode,
wherein after a same common voltage is applied to each of the plurality of first electrodes, different voltages are applied to neighboring first electrodes wherein the liquid crystal layer forms a Fresnel lens.
